(19) United States
(12) Patent Application Publication
(10) Pub. No.: US 2023/0416093 A1
(43) Pub. Date: Dec. 28, 2023

(54) Compounds Alkali Metal Borophosphates, Alkali Metal Borophosphates Nonlinear Optical Crystals as well as Preparation Method and Application thereof

(71) Applicant: TIANJIN UNIVERSITY OF TECHNOLOGY, Tianjin (CN)

(72) Inventors: Hongwei YU, Tianjin (CN); Haonan LIU, Tianjin (CN); Lidan JIN, Tianjin (CN); Hongping WU, Tianjin (CN); Zhanggui HU, Tianjin (CN)

(21) Appl. No.: 17/874,368

(22) Filed: Jul. 27, 2022

(30) Foreign Application Priority Data
Jun. 28, 2022 (CN) 202210743724X

(51) Int. Cl. C01B 25/30; G02F 1/355; C30B 29/14; C30B 1/10

(52) U.S. Cl. CPC C01B 25/306; C01B 25/301; G02F 1/3553; C30B 29/14; C30B 1/10; C01P 2002/76; C01P 2002/77; C01P 2002/72

(57) ABSTRACT

The present invention relates to compounds and their nonlinear optical (NLO) crystals of A₃B₁₁P₂O₂₃ (A=K, Rb, Cs), their producing method and uses thereof. A₃B₁₁P₂O₂₃ (A=K, Rb, Cs) belong to triclinic crystal system, and have a space group of P1, crystal cell parameters of a=6.284(8)-8.784(3) Å, b=6.338(3)-8.838(3) Å, c=6.463(3)-8.963(3) Å, α=70-105°, β=75-106°, γ=76-107° and Z=1 and a unit cell volume of V=257.4(3)-696.0(6) Å³. A₃B₁₁P₂O₂₃ (A=K, Rb, Cs) compounds were prepared by a high-temperature solid-state reaction method or a hydrothermal method, and A₃B₁₁P₂O₂₃ (A=K, Rb, Cs) NLO crystals were prepared by a high-temperature solid-state reaction method, a hydrothermal method or a solution method. These materials can be used to manufacture second harmonic generator, up-down frequency converter, optical parametric oscillator, etc.

### CROSS REFERENCE TO RELATED APPLICATION

The present invention relates to compounds alkali metal borophosphates with a chemical formula of A₃B₁₁P₂O₂₃ (A=K, Rb, Cs), alkali metal borophosphate nonlinear optical crystals, a preparation method of the crystals and a nonlinear optical apparatus manufactured from the crystals.

### BACKGROUND OF THE INVENTION

Deep-ultraviolet (DUV) coherent lights with wavelengths between 200 and 150 nm are of increasing importance owing to their potential applications in semiconductor photolithography, laser micromachining, modern scientific instruments. For solid-state lasers, the best way to obtain the DUV coherent lights is through the cascaded frequency conversion technology of nonlinear optical (NLO) crystals. However, for an applicable DUV NLO crystal, it must satisfy the following harsh structural and properties' requirements, including i) the non-centrosymmetric (NCS) structures; ii) large second-order NLO coefficients (dᵢⱼ), at least comparable to the d₃₆ of KDP; iii) high transparency in the DUV region with the UV cut-off wavelength as short as possible; iv) a moderate birefringence (Δn=0.05-0.10) to satisfy the phase-matching condition of second-harmonic generation (SHG) in the UV or DUV region; and v) ease of growth, non-toxic, chemical stability, and good mechanical properties. However, since some of the above properties are conflicted, e.g., the materials with large band gaps often exhibit small SHG responses and birefringence, designing and synthesizing a DUV NLO crystal is still a great challenge. Borophosphates with asymmetric [BO₄] and [PO₄] tetrahedra as basic building blocks usually have large band gaps, and are widely regarded as candidates for exploring UV or DUV optical crystals. Notably, BPO₄ has a strong second-harmonic response (2×KDP), and its UV transmittance range extends to about 130 nm. However, its small birefringence of 0.005@1064 nm makes conventional phase matching impossible, and the crystal cannot be used as a UV NLO crystal. However, π-conjugated [BO₃] groups with excellent optical anisotropy are beneficial to improve the birefringence of the material. Therefore, designing and synthesizing borophosphates with [BO₃], [BO₄] and [PO₄] groups are an effective way to design DUV NLO materials.

### SUMMARY OF THE INVENTION

The first objective of the present invention is to provide compounds alkali metal borophosphates with a chemical formula of A₃B₁₁P₂O₂₃ (A=K, Rb, Cs). Their single crystals having non-centrosymmetric structures, belong to triclinic crystal system, and have a space group of P1, crystal cell parameters of a=6.284(8)-8.784(3) Å, b=6.338(3) 8.838(3) Å, c=6.463(3)-8.963(3) Å, α=70-105°, β=75-106°, γ=76-107°, and Z=1 and a unit cell volume of V=257.4(3)-696.0(6) Å³. The polycrystalline powder was prepared through a high-temperature solid-state reaction method or a hydrothermal method.

Another objective of the present invention is to provide alkali metal borophosphate nonlinear optical crystals and a preparation method thereof. The crystals have a chemical formula of A₃B₁₁P₂O₂₃ (A=K, Rb, Cs), which are single crystals having non-centrosymmetric structures, belong to triclinic crystal system, and have a space group of P1, crystal cell parameters of a=6.284(8)-8.784(3) Å, b=6.338(3)-8.838(3) Å, c=6.463(3)-8.963(3) Å, α=70-105°, β=75-106°, γ=76-107° and Z=1 and a unit cell volume of V=257.4(3)-696.0(6) Å³. The preparation methods are solid-state reaction method, hydrothermal method and solution method of potassium/rubidium/cesium-containing compounds, boron-containing compounds, and phosphorus-containing compounds.

Another objective of the present invention is to provide the use of alkali metal borophosphate nonlinear optical apparatus in nonlinear optical devices such as second harmonic generators, up and down frequency converters, optical parametric oscillations, laser frequency conversion devices, and laser communications.

The present invention adopts the following technical solution:

The alkali metal borophosphates provided by the present invention have a chemical formula of A₃B₁₁P₂O₂₃ (A=K, Rb, Cs), and their preparation processes adopt a high-temperature solid-phase reaction method, a hydrothermal method or a solution method based on the following steps:

A mixture of a potassium/rubidium/cesium-containing compound, a boron-containing compound, a phosphorus-containing compound was thoroughly ground, and the mixture was preheated to 350-1000° C., held for a period of time, with several intermediate grindings to get the A₃B₁₁P₂O₂₃ (A=K, Rb, Cs) single phase, in which element potassium/rubidium/cesium in the potassium/rubidium/cesium-containing compound, elemental boron in the boron-containing compound, and elemental phosphorus in the phosphorus-containing compound are in a molar ratio of 2.5-3.5:9-13:1-3.

Or a. a mixture of a potassium/rubidium/cesium-containing compound, a boron-containing compound, a phosphorus-containing compound was combined with deionized water (0.1-50 mL) or boric acid 0.1-50 g, in which element potassium/rubidium/cesium in the potassium/rubidium/cesium-containing compound, elemental boron in the boron-containing compound, and elemental phosphorus in the phosphorus-containing compound are in a molar ratio of 1-5:7-16:0.5-4;

b. The mixture was loaded into the Teflon-lined autoclave and subsequently sealed;

c. The autoclave was heated to 120-800° C., held for a period of time, and then cooled to room temperature;

d. Open the autoclave and filter the solution containing crystals to obtain transparent alkali metal borophosphates compounds.

Or a mixture of a potassium/rubidium/cesium-containing compound, a boron-containing compound, a phosphorus-containing compound, and deionized water (0.1-400 mL) was placed in a beaker and stirred until dissolved completely. Then put the beaker on the heating table and heat it to 25-400° C. After a period of time, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After a period of time, take out the centimeter size alkali metal borophosphates nonlinear optical crystals from the solution.

The potassium containing compound includes at least one of potassium hydroxide, potassium oxide and potassium salt; potassium salt includes at least one of potassium fluoride, potassium chloride, potassium bromide, potassium nitrate, potassium oxalate, potassium carbonate, potassium bicarbonate and potassium sulfate;

The rubidium containing compound includes at least one of rubidium hydroxide, rubidium oxide and rubidium salt; rubidium salt includes at least one of rubidium fluoride, rubidium chloride, rubidium bromide, rubidium nitrate, rubidium oxalate, rubidium carbonate, rubidium bicarbonate and rubidium sulfate;

The cesium containing compound includes at least one of cesium hydroxide, cesium oxide and cesium salt; cesium salt includes at least one of cesium fluoride, cesium chloride, cesium bromide, cesium nitrate, cesium oxalate, cesium carbonate, cesium bicarbonate and cesium sulfate;

The boron containing compound includes at least one of boron oxide, boric acid and boron salt; the boron salt includes at least one of boron chloride, boron bromide, boron nitrate, boron oxalate, boron carbonate and boron sulfate;

The phosphorus containing compound includes at least one of phosphorus pentoxide and phosphorus salt; the phosphorus salt includes at least one of phosphorus chloride, phosphorus bromide, phosphorus nitrate, phosphorus oxalate, phosphorus carbonate, ammonium dihydrogen phosphate, potassium dihydrogen phosphate, potassium/rubidium/cesium dihydrogen phosphate, cesium dihydrogen phosphate and phosphorus sulfate.

The alkali metal borophosphates compounds can be prepared by a high-temperature solid-phase reaction method or a hydrothermal method based on the following chemical reaction formulas:

3A₂O(A=K,Rb,Cs)+22H₃BO₃+2P₂O₅→2A₃B₁₁P₂O₂₃(A=K,Rb,Cs)+33H₂O↑ 1)

3AOH(A=K,Rb,Cs)+11H₃BO₃O₅→A₃B₁₁P₂O₂₃(A=K,Rb,Cs)+18H₂O↑ 2)

3A₂CO₃(A=K,Rb,Cs)+22H₃BO₃+2P₂O₅→2A₃B₁₁P₂O₂₃(A=K,Rb,Cs)+33H₂O↑+3CO₂↑ 3)

3A₂CO₃(A=K,Rb,Cs)+22H₃BO₃+4NH₄H₂PO₄→2A₃B₁₁P₂O₂₃(A=K,Rb,Cs)+33H₂O↑+3CO₂↑+4NH₃↑ 4)

3AF(A=K,Rb,Cs)+11H₃BO₃+2NH₄H₂PO₄→A₃B₁₁P₂O₂₃(A=K,Rb,Cs)+18H₂O↑+3HF↑+2NH₃↑ 5)

3A₂CO₃(A=K,Rb,Cs)+11B₂O₃+4NH₄H₂PO₄→2A₃B₁₁P₂O₂₃(A=K,Rb,Cs)+6H₂O↑+3CO₂↑+4NH₃↑ 6)

3A₂CO₃(A=K,Rb,Cs)+11B₂O₃+2P₂O₅→2A₃B₁₁P₂O₂₃(A=K,Rb,Cs)+3CO₂↑ 7)

3AH₂PO₄(A=K,Rb,Cs)+5.5B₂O₃→A₃B₁₁P₂O₂₃(A=K,Rb,Cs)+1.5H₂O↑+H₃PO₄ 8)

3A₂HPO₄(A=K,Rb,Cs)+11B₂O₃+0.5P₂O₅→2A₃B₁₁P₂O₂₃(A=K,Rb,Cs)+1.5H₂O↑ 9)

6AOH(A=K,Rb,Cs)+11B₂O₃+2P₂O₅→2A₃B₁₁P₂O₂₃(A=K,Rb,Cs)+3H₂O↑ 10)

12AH₂PO₄(A=K,Rb,Cs)+22H₃B₂O₃+2P₂O₅→4A₃B₁₁P₂O₂₃(A=K,Rb,Cs)+33H₂↑+8H₃PO₄ 11)

6ACl(A=K,Rb,Cs)+11B₂O₃+4NH₄H₂PO₄→2A₃B₁₁P₂O₂₃(A=K,Rb,Cs)+6HCl↑+4NH₃↑+3H₂O↑ 12)

6ACl(A=K,Rb,Cs)+22H₃BO₃+2P₂O₅→2A₃B₁₁P₂O₂₃(A=K,Rb,Cs)+6HCl↑+30H₂O↑ 13)

The alkali metal borophosphates nonlinear optical crystals provided by the present invention is characterized in that the crystals have a chemical formula of A₃B₁₁P₂O₂₃ (A=K, Rb, Cs), which are single crystals having non-centrosymmetric structures, belong to triclinic crystal system, and have a space group of P₁, crystal cell parameters of a=6.284(8)-8.784(3) Å, b=6.338(3)-8.838(3) Å, c=6.463(3)-8.963(3) Å, α=70-105°, β=75 106°, γ=76-107° and Z=1 and a unit cell volume of V=257.4(3)-696.0(6) Å³.

The alkali metal borophosphates nonlinear optical crystals provided by the present invention adopts a high-temperature solid-phase reaction method, a hydrothermal method or a solution method based on the following specific operation steps:

a. uniformly mixing the compound alkali metal borophosphates single-phase polycrystalline powder with the fluxing agents, and heat it to a temperature of 350-1000° C., and keep it at a constant temperature for a period of time to obtain a mixed melt, and then cooled to 300-900° C., in which the molar ratios of the compound alkali metal borophosphates single-phase polycrystalline powder to the fluxing agents are 1:0-20;

Or directly heat the mixture of a potassium/rubidium/cesium-containing compound, a boron-containing compound, and a phosphorus-containing compound or the mixture of a potassium/rubidium/cesium-containing compound, a boron-containing compound, a phosphorus-containing compound and the fluxing agents to 350-1000° C., and held for a period of time, to obtain a mixed melt. And then cooled to a temperature of 300-900° C., in which the molar ratios of a potassium/rubidium/cesium-containing compound, a boron-containing compound and a phosphorus-containing compound to the fluxing agents are 0.5-5:6-16:0.5-4:0-20;

The fluxing agents mainly include self-service fluxing agents, such as K₂CO₃, KF, KOH, K₂O, KCl, KBF₄, Rb₂CO₃, RbF, RbOH, Rb₂O, RbCl, RbBF₄, Cs₂CO₃, CsF, CsOH, Cs₂O, CsCl, CsBF₄, H₃BO₃, B₂O₃, KH₂PO₄, RbH₂PO₄, CsH₂PO₄, KBO₂, RbBO₂, CsBO₂, NH₄H₂PO₄, P₂O₅, etc. and other composite fluxing agents, such as KOH—H₃BO₃, KOH—B₂O₃, KOH—P₂O₅, KOH—NH₄H₂PO₄, K₂CO₃—H₃BO₃, K₂CO₃—B₂O₃, K₂CO₃—P₂O₅, K₂CO₃—NH₄H₂PO₄, KF—H₃BO₃, KF—B₂O₃, KF—P₂O₅, KF—NH₄H₂PO₄, KCl—H₃BO₃, KCl—B₂O₃, KCl—P₂O₅, KCl—NH₄H₂PO₄, K₂O—PbO, K₂O—PbF₂, KOH—PbO, KOH—PbF₂, KF—Bi₂O₃, KF—MoO₃, KBF₄—Bi₂O₃, KBF₄—MoO₃, K₂CO₃—Li₄P₂O₇, K₂CO₃—KBO₂, K₂CO₃—NaF, K₂CO₃—NaCl, K₂CO₃—Li₄P₂O₇—NaF, K₂CO₃—Li₄P₂O₇—NaCl, K₂CO₃—Li₄P₂O₇—MoO₃, K₂CO₃—LiBO₂—MoO₃, K₂CO₃—H₃BO₃—P₂O₅, K₂CO₃—H₃BO₃—NH₄H₂PO₄, K₂CO₃—H₃BO₃—PbO, RbOH—H₃BO₃, RbOH—B₂O₃, RbOH—P₂O₅, RbOH—NH₄H₂PO₄, Rb₂CO₃—H₃BO₃, Rb₂CO₃—B₂O₃, Rb₂CO₃—P₂O₅, Rb₂CO₃—NH₄H₂PO₄, RbF—H₃BO₃, RbF—B₂O₃, RbF—P₂O₅, RbF—NH₄H₂PO₄, RbCl—H₃BO₃, RbCl—B₂O₃, RbCl—P₂O₅, RbCl—NH₄H₂PO₄, Rb₂O—PbO, Rb₂O—PbF₂, RbOH—PbO, RbOH—PbF₂, RbF—Bi₂O₃, RbF—MoO₃, RbBF₄—Bi₂O₃, RbBF₄—MoO₃, Rb₂CO₃—Li₄P₂O₇, Rb₂CO₃—RbBO₂, Rb₂CO₃—NaF, Rb₂CO₃—NaCl, Rb₂CO₃—Li₄P₂O₇—NaF, Rb₂CO₃—Li₄P₂₀₇—NaCl, Rb₂CO₃—Li₄P₂O₇—MoO₃, Rb₂CO₃—LiBO₂—MoO₃, Rb₂CO₃—H₃BO₃—P₂O₅, Rb₂CO₃—H₃BO₃—NH₄H₂PO₄, Rb₂CO₃—H₃BO₃—PbO, CsOH—H₃BO₃, CsOH—B₂O₃, CsOH—P₂O₅, CsOH—NH₄H₂PO₄, Cs₂CO₃—H₃BO₃, Cs₂CO₃—B₂O₃, Cs₂CO₃—P₂O₅, Cs₂CO₃—NH₄H₂PO₄, CSF—H₃BO₃, CSF—B₂O₃, CSF—P₂O₅, CsF—NH₄H₂PO₄, CsCl—H₃BO₃, CsCl—B₂O₃, CsCl—P₂O₅, CsCl—NH₄H₂PO₄, H₃BO₃—P₂O₅, H₃BO₃—NH₄H₂PO₄, B₂O₃—P₂O₅, B₂O₃—NH₄H₂PO₄, Cs₂O—PbO, Cs₂O—PbF₂, CsOH—PbO, CsOH—PbF₂, CsF—Bi₂O₃, CsF—MoO₃, CsBF₄—Bi₂O₃, CsBF₄—MoO₃, Cs₂CO₃—Li₄P₂O₇, Cs₂CO₃—CsBO₂, Cs₂CO₃—NaF, Cs₂CO₃—NaCl, Cs₂CO₃—Li₄P₂O₇—NaF, Cs₂CO₃—Li₄P₂O₇—NaCl, Cs₂CO₃—Li₄P₂O₇—MoO₃, Cs₂CO₃—LiBO₂—MoO₃, Cs₂CO₃—H₃B₀₃—P₂O₅, Cs₂CO₃—H₃BO₃—NH₄H₂PO₄, Cs₂CO₃—H₃BO₃—PbO, etc.

The compound alkali metal borophosphates single-phase polycrystalline powder are prepared by a solid-state method, including the following steps: mixing a potassium/rubidium/cesium-containing compound, a boron-containing compound and a phosphorus-containing compound by a solid-state method to obtain the compound alkali metal borophosphates. The element potassium/rubidium/cesium in the potassium/rubidium/cesium-containing compound, the element boron in the boron-containing compound, and the element phosphorus in the phosphorus-containing compound are in a molar ratio of 2.5-3.5:9-13:1-3, and the raw materials of the potassium/rubidium/cesium-containing compound, the boron-containing compound and the phosphorus-containing compound are mixed uniformly. After grinding, the mixture was pre-fired to remove moisture and gas, and then cool to room temperature. Further, the mixture was gradually heated to 350-1000° C., held at this temperature for a period of time. The compounds alkali metal borophosphates single-phase polycrystalline powder are obtained.

b. Preparation of alkali metal borophosphates seed crystals: the mixture obtained in step (a) is slowly cooled to room temperature, and spontaneously crystallized to obtain alkali metal borophosphate seeds;

c. A seed crystal of A₃B₁₁P₂O₂₃ (A=K, Rb, Cs) was attached with Pt wire to a Pt rod. After being preheated above the solution surface, the seed was introduced into the melt, and held the temperature for a period of time, the temperature of the furnace was lowered quickly to the initial crystallization temperature.

d. Continue to cool down slowly, and rotate the seed crystal rod to grow the crystal. When the growth was completed, the crystal was drawn out of the melt surface, and the temperature dropped to room temperature, and then obtain the alkali metal borophosphates nonlinear optical crystals.

The molar ratio of KOH to B₂O₃ in the KOH—B₂O₃ system of the fluxing agent is 0.5-4:6-12; the molar ratio of KOH to P₂O₅ in the KOH—P₂O₅ system is 0.5-5:6-15; the molar ratio of KOH to NH₄H₂PO₄ in the KOH—NH₄H₂PO₄ system is 1-4:7-12; the molar ratio of K₂CO₃ to H₃BO₃ in the K₂CO₃—H₃BO₃ system is 0.5-3:8-16; the molar ratio of K₂CO₃ to B₂O₃ in the K₂CO₃—B₂O₃ system is 1-3:9-16; the molar ratio of K₂CO₃ to P₂O₅ in the K₂CO₃—P₂O₅ system is 0.5-2:6-12; the molar ratio of K₂CO₃ to NH₄H₂PO₄ in the K₂CO₃—NH₄H₂PO₄ system is 1-4:11-16; the molar ratio of KF to H₃BO₃ in the KF—H₃BO₃ system is 0.5-4:8-15; the molar ratio of KF to B₂O₃ in the KF—B₂O₃ system is 0.5-3:6-15; the molar ratio of KF to P₂O₅ in the KF—P₂O₅ system is 0.5-3:7-10; the molar ratio of KF to NH₄H₂PO₄ in the KF—NH₄H₂PO₄ system is 0.5-3:6-10; the molar ratio of KCl to H₃BO₃ in the KCl—H₃BO₃ system is 0.5-3.5:6-14; the molar ratio of KCl to B₂O₃ in the KCl—B₂O₃ system is 0.5-3.5:6-14; the molar ratio of KCl to P₂O₅ in the KCl—P₂O₅ system is 0.5-3.5:7-15; the molar ratio of KCl to NH₄H₂PO₄ in the KCl—NH₄H₂PO₄ system is 0.5-5:6-15; the molar ratio of K₂O to PbO in the K₂O—PbO system is 0.5-5: 6-16; the molar ratio of K₂O to PbF₂ in the K₂O—PbF₂ system is 0.5-5:6-16; the molar ratio of KOH to PbO in the KOH—PbO system is 0.5-5:6-16; the molar ratio of the KOH to PbF₂ in the KOH—PbF₂ system is 0.5-5:6-16; the molar ratio of the KF to Bi₂O₃ in the KF—Bi₂O₃ system is 0.5-5:6-16; the molar ratio of the KF to MoO₃ in the KF—MoO₃ system is 0.5-5:6-16; the molar ratio of the KBF₄ to Bi₂O₃ in the KBF₄—Bi₂O₃ system is 0.5-5:6-16; the molar ratio of the KBF₄ to MoO₃ in the KBF₄—MoO₃ system is 0.5-5:6-16; the molar ratio of K₂CO₃ to Li₄P₂O₇ in the K₂CO₃—Li₄P₂O₇ system is 0.5-3.5:7-15; the molar ratio of K₂CO₃ to KBO₂ in the K₂CO₃—KBO₂ system is 0.5-5:6-15; the molar ratio of K₂CO₃ to NaF in the K₂CO₃—NaF system is 0.5-3.5:7-15; the molar ratio of K₂CO₃ to NaCl in the K₂CO₃—NaCl system is 0.5-5:6-15; the molar ratio of K₂CO₃, Li₄P₂O₇ to NaF in the K₂CO₃—Li₄P₂O₇—NaF system is 0.5-5:6-16:6-16; the molar ratio of K₂CO₃, Li₄P₂O₇ to NaCl in the K₂CO₃—Li₄P₂O₇—NaCl system is 0.5-5:6-16:6-16; the molar ratio of K₂CO₃, Li₄P₂O₇ to MoO₃ in the K₂CO₃—Li₄P₂O₇— MoO₃ system is 0.5-5:6-16:6-16; the molar ratio of K₂CO₃, LiBO₂ to MoO₃ in the K₂CO₃— LiBO₂— MoO₃ system is 0.5-5:6-16:6-16; the molar ratio of K₂CO₃, H₃BO₃ to P₂O₅ in the K₂CO₃—H₃BO₃—P₂O₅ system is 0.5-5:6-16:6-16; the molar ratio of K₂CO₃, H₃BO₃ to NH₄H₂PO₄ in the K₂CO₃—H₃BO₃—NH₄H₂PO₄ system is 0.5-5:6-16:6-16; the molar ratio of K₂CO₃, H₃BO₃ to PbO in the K₂CO₃—H₃BO₃—PbO system is 0.5-5:6-16: 6-16; the molar ratio of RbOH to B₂O₃ in the RbOH—B₂O₃ system is 0.5-4:6-12; the molar ratio of RbOH to P₂O₅ in the RbOH—P₂O₅ system is 0.5-5:6-15; the molar ratio of RbOH to NH₄H₂PO₄ in the RbOH—NH₄H₂PO₄ system is 1-4:7-12; the molar ratio of Rb₂CO₃ to H₃BO₃ in the Rb₂CO₃—H₃BO₃ system is 0.5-3:8-16; the molar ratio of Rb₂CO₃ to B₂O₃ in the Rb₂CO₃—B₂O₃ system is 1-3:9-16; the molar ratio of Rb₂CO₃ to P₂O₅ in the Rb₂CO₃—P₂O₅ system is 0.5-2:6-12; the molar ratio of Rb₂CO₃ to NH₄H₂PO₄ in the Rb₂CO₃—NH₄H₂PO₄ system is 1-4:11-16; the molar ratio of RbF to H₃BO₃ in the RbF—H₃BO₃ system is 0.5-4:8-15; the molar ratio of RbF to B₂O₃ in the RbF—B₂O₃ system is 0.5-3:6-15; the molar ratio of RbF to P₂O₅ in the RbF—P₂O₅ system is 0.5-3:7-10; the molar ratio of RbF to NH₄H₂PO₄ in the RbF—NH₄H₂PO₄ system is 0.5-3:6-10; the molar ratio of RbCl to H₃BO₃ in the RbCl—H₃BO₃ system is 0.5-3.5:6-14; the molar ratio of RbCl to B₂O₃ in the RbCl—B₂O₃ system is 0.5-3.5:6-14; the molar ratio of RbCl to P₂O₅ in the RbCl—P₂O₅ system is 0.5-3.5:7-15; the molar ratio of RbCl to NH₄H₂PO₄ in the RbCl—NH₄H₂PO₄ system is 0.5-5:6-15; the molar ratio of Rb₂O to PbO in the Rb₂O—PbO system is 0.5-5: 6-16; the molar ratio of Rb₂O to PbF₂ in the Rb₂O—PbF₂ system is 0.5-5:6-16; the molar ratio of RbOH to PbO in the RbOH—PbO system is 0.5-5:6-16; the molar ratio of the RbOH to PbF₂ in the RbOH—PbF₂ system is 0.5-5:6-16; the molar ratio of the RbF to Bi₂O₃ in the RbF—Bi₂O₃ system is 0.5-5:6-16; the molar ratio of the RbF to MoO₃ in the RbF—MoO₃ system is 0.5-5:6-16; the molar ratio of the RbBF₄ to Bi₂O₃ in the RbBF₄—Bi₂O₃ system is 0.5-5:6-16; the molar ratio of the RbBF₄ to MoO₃ in the RbBF₄—MoO₃ system is 0.5-5:6-16; the molar ratio of Rb₂CO₃ to Li₄P₂O₇ in the Rb₂CO₃—Li₄P₂O₇ system is 0.5-3.5:7-15; the molar ratio of Rb₂CO₃ to RbBO₂ in the Rb₂CO₃—RbBO₂ system is 0.5-5:6-15; the molar ratio of Rb₂CO₃ to NaF in the Rb₂CO₃—NaF system is 0.5-3.5:7-15; the molar ratio of Rb₂CO₃ to NaCl in the Rb₂CO₃—NaCl system is 0.5-5:6-15; the molar ratio of Rb₂CO₃, Li₄P₂O₇ to NaF in the Rb₂CO₃—Li₄P₂O₇—NaF system is 0.5-5:6-16:6-16; the molar ratio of Rb₂CO₃, Li₄P₂O₇ to NaCl in the Rb₂CO₃—Li₄P₂O₇—NaCl system is 0.5-5:6-16:6-16; the molar ratio of Rb₂CO₃, Li₄P₂O₇ to MoO₃ in the Rb₂CO₃—Li₄P₂O₇— MoO₃ system is 0.5-5:6-16:6-16; the molar ratio of Rb₂CO₃, LiBO₂ to MoO₃ in the Rb₂CO₃— LiBO₂— MoO₃ system is 0.5-5:6-16:6-16; the molar ratio of Rb₂CO₃, H₃BO₃ to P₂O₅ in the Rb₂CO₃—H₃BO₃—P₂O₅ system is 0.5-5:6-16:6-16; the molar ratio of Rb₂CO₃, H₃BO₃ to NH₄H₂PO₄ in the Rb₂CO₃—H₃BO₃—NH₄H₂PO₄ system is 0.5-5:6-16:6-16; the molar ratio of Rb₂CO₃, H₃BO₃ to PbO in the Rb₂CO₃—H₃B₀₃—PbO system is 0.5-5:6-16: 6-16; the molar ratio of CsOH to B₂O₃ in the CsOH—B₂O₃ system is 0.5-4:6-12; the molar ratio of CsOH to P₂O₅ in the CsOH—P₂O₅ system is 0.5-5:6-15; the molar ratio of CsOH to NH₄H₂PO₄ in the CsOH—NH₄H₂PO₄ system is 1-4:7-12; the molar ratio of Cs₂CO₃ to H₃BO₃ in the Cs₂CO₃—H₃BO₃ system is 0.5-3:8-16; the molar ratio of Cs₂CO₃ to B₂O₃ in the Cs₂CO₃—B₂O₃ system is 1-3:9-16; the molar ratio of Cs₂CO₃ to P₂O₅ in the Cs₂CO₃—P₂O₅ system is 0.5-2:6-12; the molar ratio of Cs₂CO₃ to NH₄H₂PO₄ in the Cs₂CO₃—NH₄H₂PO₄ system is 1-4:11-16; the molar ratio of CsF to H₃BO₃ in the CsF—H₃BO₃ system is 0.5-4:8-15; the molar ratio of CsF to B₂O₃ in the CsF—B₂O₃ system is 0.5-3:6-15; the molar ratio of CsF to P₂O₅ in the CsF—P₂O₅ system is 0.5-3:7-10; the molar ratio of CsF to NH₄H₂PO₄ in the CsF—NH₄H₂PO₄ system is 0.5-3:6-10; the molar ratio of CsCl to H₃BO₃ in the CsCl—H₃BO₃ system is 0.5-3.5:6-14; the molar ratio of CsCl to B₂O₃ in the CsCl—B₂O₃ system is 0.5-3.5:6-14; the molar ratio of CsCl to P₂O₅ in the CsCl—P₂O₅ system is 0.5-3.5:7-15; the molar ratio of CsCl to NH₄H₂PO₄ in the CsCl—NH₄H₂PO₄ system is 0.5-5:6-15; the molar ratio of H₃BO₃ to P₂O₅ in the H₃BO₃—P₂O₅ system is 0.5-5:6-16; the molar ratio of H₃BO₃ to NH₄H₂PO₄ in the H₃BO₃—NH₄H₂PO₄ system is 0.5-5:6-16; the molar ratio of B₂O₃ to P₂O₅ in the B₂O₃—P₂O₅ system is 0.5-5:6-16; the molar ratio of B₂O₃ to NH₄H₂PO₄ in the B₂O₃—NH₄H₂PO₄ system is 0.5-5:6-16; the molar ratio of H₃BO₃ to NH₄H₂PO₄ in the H₃BO₃—NH₄H₂PO₄ system is 0.5-5:6-16; the molar ratio of Cs₂O to PbO in the Cs₂O—PbO system is 0.5-5: 6-16; the molar ratio of Cs₂O to PbF₂ in the Cs₂O—PbF₂ system is 0.5-5:6-16; the molar ratio of CsOH to PbO in the CsOH—PbO system is 0.5-5:6-16; the molar ratio of the CsOH to PbF₂ in the CsOH—PbF₂ system is 0.5-5:6-16; the molar ratio of the CsF to Bi₂O₃ in the CsF—Bi₂O₃ system is 0.5-5:6-16; the molar ratio of the CsF to MoO₃ in the CsF—MoO₃ system is 0.5-5:6-16; the molar ratio of the CsBF₄ to Bi₂O₃ in the CsBF₄—Bi₂O₃ system is 0.5-5:6-16; the molar ratio of the CsBF₄ to MoO₃ in the CsBF₄—MoO₃ system is 0.5-5:6-16; the molar ratio of Cs₂CO₃ to Li₄P₂O₇ in the Cs₂CO₃—Li₄P₂O₇ system is 0.5-3.5:7-15; the molar ratio of Cs₂CO₃ to CsBO₂ in the Cs₂CO₃— CsBO₂ system is 0.5-5:6-15; the molar ratio of Cs₂CO₃ to NaF in the Cs₂CO₃—NaF system is 0.5-3.5:7-15; the molar ratio of Cs₂CO₃ to NaCl in the Cs₂CO₃—NaCl system is 0.5-5:6-15; the molar ratio of Cs₂CO₃, Li₄P₂O₇ to NaF in the Cs₂CO₃—Li₄P₂O₇—NaF system is 0.5-5:6-16:6-16; the molar ratio of Cs₂CO₃, Li₄P₂O₇ to NaCl in the Cs₂CO₃—Li₄P₂O₇—NaCl system is 0.5-5:6-16:6-16; the molar ratio of Cs₂CO₃, Li₄P₂O₇ to MoO₃ in the Cs₂CO₃—Li₄P₂O₇— MoO₃ system is 0.5-5:6-16:6-16; the molar ratio of Cs₂CO₃, LiBO₂ to MoO₃ in the Cs₂CO₃— LiBO₂— MoO₃ system is 0.5-5:6-16:6-16; the molar ratio of Cs₂CO₃, H₃BO₃ to P₂O₅ in the Cs₂CO₃—H₃BO₃—P₂O₅ system is 0.5-5:6-16:6-16; the molar ratio of Cs₂CO₃, H₃BO₃ to NH₄H₂PO₄ in the Cs₂CO₃—H₃B₀₃—NH₄H₂PO₄ system is 0.5-5:6-16:6-16; the molar ratio of Cs₂CO₃, H₃BO₃ to PbO in the Cs₂CO₃—H₃BO₃—PbO system is 0.5-5:6-16: 6-16.

Or a. a mixture of a potassium/rubidium/cesium-containing compound, a boron-containing compound, a phosphorus-containing compound were combined with deionized water (0.1-50 mL) or boric acid 0.1-50 g, in which element potassium/rubidium/cesium in the potassium/rubidium/cesium-containing compound, elemental boron in the boron-containing compound, and elemental phosphorus in the phosphorus-containing compound are in a molar ratio of 1-5:7-16:0.5-4;

b. The mixture was loaded into Teflon-lined autoclave and subsequently sealed;

c. The autoclave was heated to 120-800° C., held for a period of time, and then cooled to room temperature;

d. Open the autoclave and filter the solution containing crystals to obtain a transparent alkali metal borophosphates compounds.

Or a mixture of a potassium/rubidium/cesium-containing compound, a boron-containing compound, a phosphorus-containing compound, and deionized water (0.1-400 mL) was placed in a beaker and stirred until dissolved completely. Then put the beaker on the heating table and heat it to 25-400° C. After a period of time, a series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After a period of time, take out a centimeter size alkali metal borophosphates nonlinear optical crystals from the solution.

The alkali metal borophosphates crystals have the advantages of high purity, easy crystal growth, transparent and no package, fast growth speed, low cost and easy to obtain large-size crystals; the obtained crystals have the advantages of wide light transmission band, high hardness, good mechanical properties, not easy to break and deliquescence, and easy to process and preserve. The nonlinear optical device made of the compounds potassium/rubidium/cesium borophosphates nonlinear optical crystals obtained by the method of the invention uses a Nd:YAG Q-switched laser as the light source at room temperature, the incident wavelength is 1064 nm infrared light, and the output wavelength is 532 nm green laser.

### BRIEF DESCRIPTION OF THE FIGURES

FIG. 1 is an X-ray powder diffraction pattern of a compound A₃B₁₁P₂O₂₃ (A=K, Rb, Cs) of the present invention;

FIG. 2 is a structural diagram of a A₃B₁₁P₂O₂₃ (A=K, Rb, Cs) crystal of the present invention;

FIG. 3 is a working schematic diagram of a nonlinear optical apparatus manufactured from A₃B₁₁P₂O₂₃ (A=K, Rb, Cs) crystal of the present invention, where 1 is a laser device, 2 is a condensing lens, 3 is a A₃B₁₁P₂O₂₃ (A=K, Rb, Cs) crystal, 4 is a beam splitting prism and 5 is a light filter.

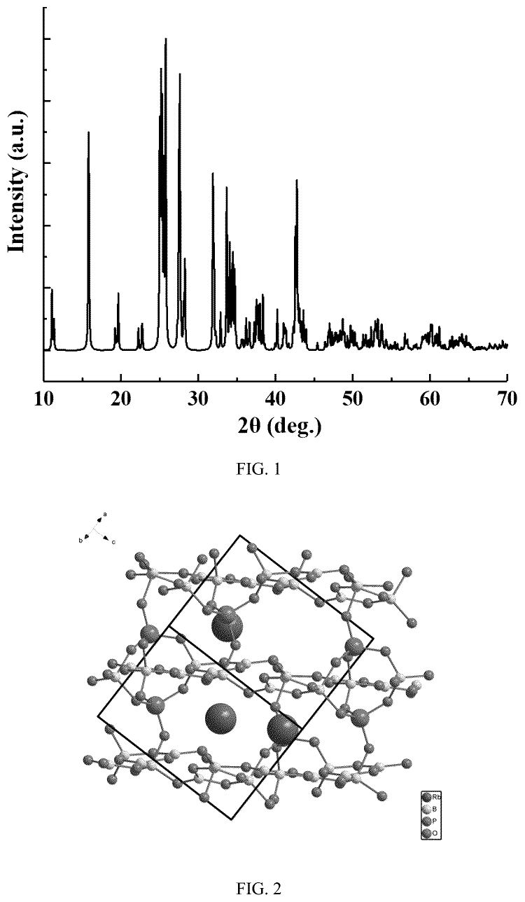

### DETAILED DESCRIPTION OF THE PREFERRED EMBODIMENTS

The present invention is described above through specific embodiments, but the invention is not limited to these embodiments.

### Embodiment 1

A₃B₁₁P₂O₂₃ (A=K, Rb, Cs) polycrystalline powder was prepared according to a reaction formula: 3A₂O (A=K, Rb, Cs)+22H₃BO₃+2P₂O₅→2A₃B₁₁P₂O₂₃ (A=K, Rb, Cs)+33H₂O↑ as follows:

Reagents were weighed according to stoichiometric proportion and were put in a mortar and then mixed and ground carefully. The mixture was put in a lidless corundum crucible of size of Φ 100 mm×100 mm. The said crucible was put into a muffle furnace, heated to 300° C. slowly and held this temperature for 24 hours. After being cooled down, the loose and porous sample was taken out of the crucible and was once again mixed thoroughly, ground and put back to the crucible and compacted. The mixture was heated at 750° C. for 24 h and cooled to room temperature. The sample was then taken out and ground thoroughly, and the mixture was put back to the crucible and heated at 750° C. for 48 h. The product was analyzed by the powder X-ray diffraction of the product, where the X-ray diffraction pattern was consistent with a theoretical X-ray diffraction pattern of A₃B₁₁P₂O₂₃ (A=K, Rb, Cs) analyzed by a single-crystal structure.

Preparation of A₃B₁₁P₂O₂₃ (A=K, Rb, Cs) crystal by fluxing agent method: A₂O(A=K, Rb, Cs)—H₃BO₃ as the fluxing agent system, the compound of A₃B₁₁P₂O₂₃ (A=K, Rb, Cs) is used as the solute, the molar ratio of solute/fluxing agent was selected at 1:3. Then, mixed homogeneously and put into a Φ 80 mm×80 mm lidless platinum crucible which was placed in the center of a vertical, programmable temperature furnace, was heated at 850° C. until the melt became transparent and clear, held at this temperature for 15 h, and then quickly cooled to the initial crystallization temperature (650° C.). Then, a platinum wire was promptly dipped into the solution. The temperature was decreased at a rate of 0.5° C./h, then the platinum wire was pulled out of the solution, and allowed to cool to room temperature at a rate of 10° C./h.

Thus, a few colorless, transparent plate crystals crystallized on the platinum wire. The obtained crystals could be used as seeds. A seed crystal of A₃B₁₁P₂O₂₃ (A=K, Rb, Cs) was attached with Pt wire to a Pt rod and then suspended on solution at 730° C. for a quarter. The seed crystal was kept at this temperature in solution for half an hour while rotating at a rate of 10 rpm. The temperature of the furnace was first lowered quickly to 650° C. and then lowered at a rate of 2° C./day. After the growth of crystal ended, the crystal was lifted out of liquid surface. The temperature of the crystal was then lowered to room temperature at a rate of 10° C./h. As a result, transparent A₃B₁₁P₂O₂₃ (A=K, Rb, Cs) crystals with a size of 56 mm×40 mm×30 mm was obtained.

### Embodiment 2

A₃B₁₁P₂O₂₃ (A=K, Rb, Cs) polycrystalline powder was prepared according to a reaction formula: 3AOH (A=K, Rb, Cs)+11H₃BO₃O₅→A₃B₁₁P₂O₂₃ (A=K, Rb, Cs)+18H₂O↑ as follows:

Reagents were weighed according to stoichiometric proportion, preparation of A₃B₁₁P₂O₂₃ (A=K, Rb, Cs) crystal by fluxing agent method: AOH (A=K, Rb, Cs)—P₂O₅ as the fluxing agent system, the said reagents are used as the solute with the molar ratio of solute:fluxing agent=1:4, the molar ratio of AOH (A=K, Rb, Cs)/P₂O₅ was selected at 3/5. Then, mixed the said reagents with fluxing agent and put into a Φ 80 mm×80 mm lidless platinum crucible which was placed in the center of a vertical, programmable temperature furnace, was heated at 1000° C., held at this temperature for 60 h, and then quickly cooled to the initial crystallization temperature (850° C.).

The temperature was decreased to room temperature at a rate of 1.5° C./h to obtain the seeds.

A seed crystal of A₃B₁₁P₂O₂₃ (A=K, Rb, Cs) was attached with Pt wire to a Pt rod and then suspended on solution at 800° C. for ten minutes. The seed crystal was kept at this temperature in solution for half an hour while rotating at a rate of 10 rpm. The temperature of the furnace was first lowered quickly to 600° C. and then lowered at a rate of 1° C./day. After the growth of crystal ended, the crystal was lifted out of liquid surface. The temperature of the crystal was then lowered to room temperature at a rate of 20° C./h. As a result, transparent A₃B₁₁P₂O₂₃ (A=K, Rb, Cs) crystals with a size of 36 mm×22 mm×15 mm was obtained.

### Embodiment 3

A₃B₁₁P₂O₂₃ (A=K, Rb, Cs) polycrystalline powder was prepared according to a reaction formula: 3A₂CO₃ (A=K, Rb, Cs)+22H₃BO₃+2P₂O₅→2A₃B₁₁P₂O₂₃ (A=K, Rb, Cs)+33H₂O↑+3CO₂↑ as follows:

The said polycrystalline A₃B₁₁P₂O₂₃ (A=K, Rb, Cs) is used as the solute with the molar ratio of solute:fluxing agent (H₃BO₃—P₂O₅)=1:3. Then, mixed homogeneously and put into a Φ 80 mm×80 mm lidless platinum crucible which was placed in the center of a vertical, programmable temperature furnace, was heated at 350° C. until the melt became transparent and clear, held at this temperature for 60 h, and then quickly cooled to the initial crystallization temperature (330° C.).

The temperature was decreased to room temperature at a rate of 3.5° C./h to obtain the seeds.

A seed crystal of A₃B₁₁P₂O₂₃ (A=K, Rb, Cs) was attached with Pt wire to a Pt rod and then suspended on solution for 15 minutes. The seed crystal was kept at this temperature in solution for twenty minutes while rotating at a rate of 5 rpm. The temperature of the furnace was first lowered quickly to 315° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs) crystals with a size of 25 mm×24 mm×10 mm was obtained.

### Embodiment 4

A₃B₁₁P₂O₂₃ (A=K, Rb, Cs) polycrystalline powder was prepared according to a reaction formula: 3A₂CO₃ (A=K, Rb, Cs)+22H₃BO₃+4NH₄H₂PO₄→2A₃B₁₁P₂O₂₃ (A=K, Rb, Cs)+33H₂O↑+3CO₂↑+4NH₃↑ as follows:
a. Reagents were weighed according to stoichiometric proportion, and loaded into a 21 mL Teflon-lined autoclave, further added 3 mL deionized water to obtain the mixed liquid.
b. The mixture was loaded into Teflon-lined autoclave and subsequently sealed;
c. The autoclave was heated to 120° C. at a rate of 20° C./h, held for 5 days, and then cooled to room temperature at a rate of 4° C./h;
d. Open the autoclave and filter the solution containing crystals to obtain a transparent alkali metal borophosphates compounds.

### Embodiment 5

A₃B₁₁P₂O₂₃ (A=K, Rb, Cs) polycrystalline powder was prepared according to a reaction formula: 3AF (A=K, Rb, Cs)+11H₃BO₃+2NH₄H₂PO₄→A₃B₁₁P₂O₂₃ (A=K, Rb, Cs)+18 H₂O↑+3HF↑+2NH₃↑ as follows:
a. Reagents were weighed according to stoichiometric proportion, and loaded into a 150 mL Teflon-lined autoclave, further added 50 mL deionized water to obtain the mixed liquid.
b. The mixture was loaded into Teflon-lined autoclave and subsequently sealed;
c. The autoclave was heated to 330° C. at a rate of 10° C./h, held for 10 days, and then cooled to room temperature at a rate of 3° C./h;
d. Open the autoclave and filter the solution containing crystals to obtain a transparent alkali metal borophosphates compounds.

### Embodiment 6

A₃B₁₁P₂O₂₃ (A=K, Rb, Cs) polycrystalline powder was prepared according to a reaction formula: 3A₂CO₃ (A=K, Rb, Cs)+11B₂O₃+4NH₄H₂PO₄→2A₃B₁₁P₂O₂₃ (A=K, Rb, Cs)+6H₂O↑+3CO₂↑+4NH₃↑ as follows:

Reagents were weighed according to stoichiometric proportion, and then the mixture was placed in a beaker (10 mL), further add 0.1 mL deionized water into the beaker and stirred until dissolved completely. Then put the beaker on the heating table and heat it to 25° C. After 2 days, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After 3 weeks, take out a centimeter size alkali metal borophosphates nonlinear optical crystals from the solution.

### Embodiment 7

A₃B₁₁P₂O₂₃ (A=K, Rb, Cs) polycrystalline powder was prepared according to a reaction formula: 3A₂CO₃ (A=K, Rb, Cs)+11B₂O₃+2P₂O₅→2A₃B₁₁P₂O₂₃ (A=K, Rb, Cs)+3CO₂↑ as follows:

Reagents were weighed according to stoichiometric proportion, and then the mixture was placed in a beaker (1000 mL), further add 400 mL deionized water into the beaker and stirred until dissolved completely. Then put the beaker on the heating table and heat it to 400° C. After 7 days, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After 5 weeks, take out a centimeter size alkali metal borophosphate nonlinear optical crystal from the solution.

### Embodiment 8

A₃B₁₁P₂O₂₃ (A=K, Rb, Cs) polycrystalline powder was prepared according to a reaction formula: 3AH₂PO₄ (A=K, Rb, Cs)+5.5B₂O₃→A₃B₁₁P₂O₂₃ (A=K, Rb, Cs)+1.5H₂O↑+H₃PO₄ as follows:

Reagents were weighed according to stoichiometric proportion, preparation of A₃B₁₁P₂O₂₃ (A=K, Rb, Cs) crystal by fluxing agent method: AOH (A=K, Rb, Cs)—PbO as the fluxing agent system, the said reagents are used as the solute with the molar ratio of solute:fluxing agent=0.5:7, the molar ratio of AOH (A=K, Rb, Cs)/PbO was selected at 1/6. Then, mixed the said reagents with fluxing agent and put into a Φ80 mm×80 mm lidless platinum crucible which was placed in the center of a vertical, programmable temperature furnace, was heated at 350° C., held at this temperature for 60 h, and then quickly cooled to the initial crystallization temperature (330° C.).

The temperature was decreased to room temperature at a rate of 3.5° C./h to obtain the seeds.

A seed crystal of A₃B₁₁P₂O₂₃ (A=K, Rb, Cs) was attached with Pt wire to a Pt rod and then suspended on solution at 330° C. for 15 minutes. The seed crystal was kept at this temperature in solution for half an hour while rotating at a rate of 10 rpm. The temperature of the furnace was first lowered quickly to 315° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs) crystals with a size of 25 mm×24 mm×10 mm was obtained.

### Embodiment 9

A₃B₁₁P₂O₂₃ (A=K, Rb, Cs) polycrystalline powder was prepared according to a reaction formula: 3A₂HPO₄ (A=K, Rb, Cs)+11B₂O₃+0.5P₂O₅→2A₃B₁₁P₂O₂₃ (A=K, Rb, Cs)+1.5H₂O↑ as follows:

Reagents were weighed according to stoichiometric proportion, preparation of A₃B₁₁P₂O₂₃ (A=K, Rb, Cs) crystal by fluxing agent method: A₂CO₃(A=K, Rb, Cs)—H₃BO₃—NH₄H₂PO₄ as the fluxing agent system, the said reagents are used as the solute with the molar ratio of solute:fluxing agent=5:2, the molar ratio of A₂CO₃(A=K, Rb, Cs)/H₃BO₃/NH₄H₂PO₄ was selected at 5/16/16. Then, mixed the said reagents with fluxing agent and put into a Φ 80 mm×80 mm lidless platinum crucible which was placed in the center of a vertical, programmable temperature furnace, was heated at 350° C., held at this temperature for 60 h, and then quickly cooled to the initial crystallization temperature (330° C.).

The temperature was decreased to room temperature at a rate of 3.5° C./h to obtain the seeds.

A seed crystal of A₃B₁₁P₂O₂₃ (A=K, Rb, Cs) was attached with Pt wire to a Pt rod and then suspended on solution at 330° C. for 15 minutes. The seed crystal was kept at this temperature in solution for half an hour while rotating at a rate of 10 rpm. The temperature of the furnace was first lowered quickly to 315° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs) crystals with a size of 25 mm×24 mm×10 mm was obtained.

### Embodiment 10

A₃B₁₁P₂O₂₃ (A=K, Rb, Cs) polycrystalline powder was prepared according to a reaction formula: 6AOH (A=K, Rb, Cs)+11B₂O₃+2P₂O₅→2A₃Bi₁P₂O₂₃ (A=K, Rb, Cs)+3H₂O↑ as follows:

Reagents were weighed according to stoichiometric proportion, preparation of A₃B₁₁P₂O₂₃ (A=K, Rb, Cs) crystal by fluxing agent method: ABF₄-MoO₃ as the fluxing agent system, the said reagents are used as the solute with the molar ratio of solute:fluxing agent=9:3, the molar ratio of ABF₄/MoO₃ was selected at 4/7. Then, mixed the said reagents with fluxing agent and put into a Φ 80 mm×80 mm lidless platinum crucible which was placed in the center of a vertical, programmable temperature furnace, was heated at 350° C., held at this temperature for 60 h, and then quickly cooled to the initial crystallization temperature (330° C.).

The temperature was decreased to room temperature at a rate of 3.5° C./h to obtain the seeds.

A seed crystal of A₃B₁₁P₂O₂₃ (A=K, Rb, Cs) was attached with Pt wire to a Pt rod and then suspended on solution at 330° C. for 15 minutes. The seed crystal was kept at this temperature in solution for half an hour while rotating at a rate of 10 rpm. The temperature of the furnace was first lowered quickly to 315° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs) crystals with a size of 25 mm×24 mm×10 mm was obtained.

### Embodiment 11

A₃B₁₁P₂O₂₃ (A=K, Rb, Cs) polycrystalline powder was prepared according to a reaction formula: 12AH₂PO₄ (A=K, Rb, Cs)+22H₃B₂O₃+2P₂O₅→4A₃B₁₁P₂O₂₃ (A=K, Rb, Cs)+33H₂↑+8H₃PO₄ as follows:
a. Reagents were weighed according to stoichiometric proportion, and loaded into a 100 mL Teflon-lined autoclave, further added 50 g H₃BO₃ to obtain the mixed liquid.
b. The mixture was loaded into Teflon-lined autoclave and subsequently sealed;
c. The autoclave was heated to 180° C. at a rate of 20° C./h, held for 10 days, and then cooled to room temperature at a rate of 4° C./h;
d. Open the autoclave and filter the solution containing crystals to obtain a transparent alkali metal borophosphates compounds.

### Embodiment 12

A₃B₁₁P₂O₂₃ (A=K, Rb, Cs) polycrystalline powder was prepared according to a reaction formula: 6ACl (A=K, Rb, Cs)+11B₂O₃+4NH₄H₂PO₄→2A₃B₁₁P₂O₂₃ (A=K, Rb, Cs)+6HCl↑+4NH₃↑+3H₂O↑ as follows:
a. Reagents were weighed according to stoichiometric proportion, and loaded into a 21 mL Teflon-lined autoclave, further added 0.1 g H₃BO₃ to obtain the mixed liquid.
b. The mixture was loaded into Teflon-lined autoclave and subsequently sealed;
c. The autoclave was heated to 160° C. at a rate of 10° C./h, held for 11 days, and then cooled to room temperature at a rate of 4° C./h;
d. Open the autoclave and filter the solution containing crystals to obtain a transparent alkali metal borophosphates compounds.

### Embodiment 13

A₃B₁₁P₂O₂₃ (A=K, Rb, Cs) polycrystalline powder was prepared according to a reaction formula: 6ACl (A=K, Rb, Cs)+22H₃BO₃+2P₂O₅→2A₃B₁₁P₂O₂₃ (A=K, Rb, Cs)+6HCl↑+30H₂O↑ as follows:

Reagents were weighed according to stoichiometric proportion, and then the mixture was placed in a beaker (10 mL), further add 0.1 mL deionized water into the beaker and stirred until dissolved completely. Then put the beaker on the heating table and heat it to 400° C. After 7 days, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After 5 weeks, take out a centimeter size alkali metal borophosphate nonlinear optical crystal from the solution.

### Embodiment 14

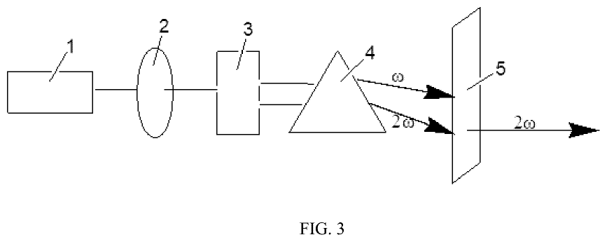

Any alkali metal borophosphates nonlinear optical crystals obtained according to embodiments 1 to 13 was mounted on the position of 3 as shown in FIG. 3; a Q-switched Nd: YAG laser device was taken as a light source with an incident wavelength of 1064 nm at the room temperature. An infrared light beam 2 with a wavelength of 1064 nm emitted by the Q-switched Nd: YAG laser device 1 came into A₃B₁₁P₂O₂₃ (A=K, Rb, Cs) single crystal 3 to generate frequency-doubled laser with a wavelength of 532 nm; and an outgoing beam 4 contained infrared light with a wavelength of 1064 nm and light with a wavelength of 532 nm, and frequency-doubled laser with a wavelength of 532 nm was obtained after the light was filtered by a light filter 5.

What is claimed is:

1. The compounds alkali metal borophosphates, wherein the compounds have a chemical formula of A₃B₁₁P₂O₂₃ (A=K, Rb, Cs), which belong to triclinic crystal system, with unit-cell parameters a=6.284(8)-8.784(3) Å, b=6.338(3)-8.838(3) Å, c=6.463(3)-8.963(3) Å, α=70-105°, β=75-106°, γ=76-107°, and Z=1 and unit cell volumes of V=257.4(3)-696.0(6) Å³.

2. The preparation method for the compounds alkali metal borophosphates according to claim 1, comprising the following steps: performing a solid-phase reaction method after mixing a potassium/rubidium/cesium-containing compound, a boron-containing compound, a phosphorus-containing compound to obtain the compounds alkali metal borophosphates, wherein the element potassium/rubidium/cesium in the potassium/rubidium/cesium-containing compounds, the element boron in the boron-containing compounds, and the element phosphorus in the phosphorus-containing compounds are in a molar ratio of 2.5-3.5:9-13:1-3.
The potassium containing compounds include at least one of potassium hydroxide, potassium oxide and potassium salt; potassium salt includes at least one of potassium fluoride, potassium chloride, potassium bromide, potassium nitrate, potassium oxalate, potassium carbonate, potassium bicarbonate and potassium sulfate;
The rubidium containing compounds include at least one of rubidium hydroxide, rubidium oxide and rubidium salt; rubidium salt includes at least one of rubidium fluoride, rubidium chloride, rubidium bromide, rubidium nitrate, rubidium oxalate, rubidium carbonate, rubidium bicarbonate and rubidium sulfate;
The cesium containing compounds include at least one of cesium hydroxide, cesium oxide and cesium salt; cesium salt includes at least one of cesium fluoride, cesium chloride, cesium bromide, cesium nitrate, cesium oxalate, cesium carbonate, cesium bicarbonate and cesium sulfate;
The boron containing compounds include at least one of boron oxide, boric acid and boron salt; the boron salt includes at least one of boron chloride, boron bromide, boron nitrate, boron oxalate, boron carbonate and boron sulfate;
The phosphorus containing compounds include at least one of phosphorus pentoxide and phosphorus salt; the phosphorus salt includes at least one of phosphorus chloride, phosphorus bromide, phosphorus nitrate, phosphorus oxalate, phosphorus carbonate, ammonium dihydrogen phosphate, potassium dihydrogen phosphate, potassium/rubidium/cesium dihydrogen phosphate, cesium dihydrogen phosphate and phosphorus sulfate.

3. The preparation method for the compounds alkali metal borophosphates according to claim 2, wherein the compounds alkali metal borophosphates are prepared by a high-temperature solid-phase reaction method or a hydrothermal method comprising the following steps:
A mixture of a potassium/rubidium/cesium-containing compound, a boron-containing compound, a phosphorus-containing compound was thoroughly ground, in which the molar ratio of element potassium/rubidium/cesium in the potassium/rubidium/cesium-containing compound, elemental boron in the boron-containing compound, and elemental phosphorus in the phosphorus-containing compound is 2.5-3.5:9-13:1-3. And the mixture was preheated to 350-1000° C., held for a period of time, with several intermediate grindings to get compound A₃B₁₁P₂O₂₃ (A=K, Rb, Cs) polycrystalline powder, and performing X-ray analysis on the obtained compounds alkali metal borophosphates polycrystalline powder, wherein the X-ray diffraction patterns are consistent with the theoretical X-ray diffraction patterns of A₃B₁₁P₂O₂₃ (A=K, Rb, Cs) analyzed by single-crystal structures.
Or a. a mixture of a potassium/rubidium/cesium-containing compound, a boron-containing compound, a phosphorus-containing compound was combined with deionized water (0.1-50 mL) or boric acid 0.1-50 g, in which element potassium/rubidium/cesium in the potassium/rubidium/cesium-containing compound, elemental boron in the boron-containing compound, and elemental phosphorus in the phosphorus-containing compound are in a molar ratio of 1-5:7-16:0.5-4;
b. The mixture was loaded into Teflon-lined autoclave and subsequently sealed;
c. The autoclave was heated to 120-800° C., held for a period of time, and then cooled to room temperature;
d. Open the autoclave and filter the solution containing crystals to obtain the transparent alkali metal borophosphates compounds.

4. The alkali metal borophosphates nonlinear optical crystals, wherein the crystals have a chemical formula of A₃B₁₁P₂O₂₃ (A=K, Rb, Cs), which belong to triclinic crystal system, has a space group of P₁, with unit-cell parameters a=6.284(8)-8.784(3) Å, b=6.338(3)-8.838(3) Å, c=6.463(3)-8.963(3) Å, α=70-105°, β=75-106°, γ=76-107° and Z=1 and a unit cell volume of V=257.4(3)-696.0(6) Å³.

5. The preparation method for the alkali metal borophosphates A₃B₁₁P₂O₂₃(A=K, Rb, Cs) nonlinear optical crystals adopt a high-temperature solid-state reaction method, a hydrothermal method or a solution method based on the following specific operation steps:
A₃B₁₁P₂O₂₃ (A=K, Rb, Cs) polycrystalline powder with the stoichiometric ratios (A: B:P=3:11:2) or a mixture of the A₃B₁₁P₂O₂₃ (A=K, Rb, Cs) polycrystalline powder with fluxing agent is heated to obtain a mixed melt. Or directly heat the mixture of the potassium/rubidium/cesium-containing compound, boron-containing compound and phosphorus-containing compound or the mixture of potassium/rubidium/cesium-containing compound, boron-containing compound and phosphorus-containing compound and fluxing agents to obtain a mixed melt. The crucible of the liquid is placed in the crystal growth furnace, the seed crystal is fixed on the seed rod, and the seed crystal is brought down to the liquid surface of the mixed melt or in the mixed melt for melting back to the saturation temperature; cooling or constant temperature growth. Finally, alkali metal borophosphates nonlinear optical crystals were prepared;
Or a. a mixture of a potassium/rubidium/cesium-containing compound, a boron-containing compound, a phosphorus-containing compound was combined with deionized water (0.1-50 mL) or boric acid 0.1-50 g, in which element potassium/rubidium/cesium in the potassium/rubidium/cesium-containing compound, elemental boron in the boron-containing compound, and elemental phosphorus in the phosphorus-containing compound are in a molar ratio of 1-5:7-16:0.5-4;
b. The mixture was loaded into Teflon-lined autoclave and subsequently sealed;
c. The autoclave was heated to 120-800° C., held for a period of time, and then cooled to room temperature;
d. Open the autoclave and filter the solution containing crystals to obtain the transparent alkali metal borophosphates compounds.
Or a mixture of a potassium/rubidium/cesium-containing compound, a boron-containing compound, a phosphorus-containing compound, and deionized water (0.1-400 mL) was placed in a beaker and stirred until dissolved completely. Then put the beaker on the heating table and heat it to 25-400° C. After a period of time, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After a period of time, take out a centimeter size alkali metal borophosphates nonlinear optical crystals from the solution.

6. The method according to claim 5, wherein a molar ratio of the compound A₃B₁₁P₂O₂₃ (A=K, Rb, Cs) single-phase polycrystalline powder to the fluxing agent is 1:0-20; or a molar ratio of a potassium/rubidium/cesium-containing compound, a boron-containing compound, a phosphorus-containing compound and a fluxing agent is 0.5-5:6-16:0.5-4:0-20; The fluxing agents mainly include self-service fluxing agents, such as K₂CO₃, KF, KOH, K₂O, KCl, KBF₄, Rb₂CO₃, RbF, RbOH, Rb₂O, RbCl, RbBF₄, Cs₂CO₃, CsF, CsOH, Cs₂O, CsCl, CsBF₄, H₃BO₃, B₂O₃, KH₂PO₄, RbH₂PO₄, CsH₂PO₄, KBO₂, RbBO₂, CsBO₂, NH₄H₂PO₄, P₂O₅, etc. and other composite fluxing agents, such as KOH—H₃BO₃, KOH—B₂O₃, KOH—P₂O₅, KOH—NH₄H₂PO₄, K₂CO₃—H₃BO₃, K₂CO₃—B₂O₃, K₂CO₃—P₂O₅, K₂CO₃—NH₄H₂PO₄, KF—H₃BO₃, KF—B₂O₃, KF—P₂O₅, KF—NH₄H₂PO₄, KCl—H₃BO₃, KCl—B₂O₃, KCl—P₂O₅, KCl—NH₄H₂PO₄, K₂O—PbO, K₂O—PbF₂, KOH—PbO, KOH—PbF₂, KF—Bi₂O₃, KF—MoO₃, KBF₄—Bi₂O₃, KBF₄—MoO₃, K₂CO₃—Li₄P₂O₇, K₂CO₃—KBO₂, K₂CO₃—NaF, K₂CO₃—NaCl, K₂CO₃—Li₄P₂O₇—NaF, K₂CO₃—Li₄P₂O₇—NaCl, K₂CO₃—Li₄P₂O₇—MoO₃, K₂CO₃—LiBO₂—MoO₃, K₂CO₃—H₃BO₃—P₂O₅, K₂CO₃—H₃BO₃—NH₄H₂PO₄, K₂CO₃—H₃BO₃—PbO, RbOH—H₃BO₃, RbOH—B₂O₃, RbOH—P₂O₅, RbOH—NH₄H₂PO₄, Rb₂CO₃—H₃BO₃, Rb₂CO₃—B₂O₃, Rb₂CO₃—P₂O₅, Rb₂CO₃—NH₄H₂PO₄, RbF—H₃BO₃, RbF—B₂O₃, RbF—P₂O₅, RbF—NH₄H₂PO₄, RbCl—H₃BO₃, RbCl—B₂O₃, RbCl—P₂O₅, RbCl—NH₄H₂PO₄, Rb₂O—PbO, Rb₂O—PbF₂, RbOH—PbO, RbOH—PbF₂, RbF—Bi₂O₃, RbF—MoO₃, RbBF₄—Bi₂O₃, RbBF₄—MoO₃, Rb₂CO₃—Li₄P₂O₇, Rb₂CO₃—RbBO₂, Rb₂CO₃—NaF, Rb₂CO₃—NaCl, Rb₂CO₃—Li₄P₂O₇—NaF, Rb₂CO₃—Li₄P₂O₇—NaCl, Rb₂CO₃—Li₄P₂O₇—MoO₃, Rb₂CO₃—LiBO₂—MoO₃, Rb₂CO₃—H₃BO₃—P₂O₅, Rb₂CO₃—H₃BO₃—NH₄H₂PO₄, Rb₂CO₃—H₃BO₃—PbO, CSOH—H₃BO₃, CsOH—B₂O₃, CsOH—P₂O₅, CsOH—NH₄H₂PO₄, CS₂CO₃—H₃BO₃, CS₂CO₃—B₂O₃, CS₂CO₃—P₂O₅, CS₂CO₃—NH₄H₂PO₄, CSF—H₃BO₃, CSF—B₂O₃, CSF—P₂O₅, CSF—NH₄H₂PO₄, CSCl—H₃BO₃, CSCl—B₂O₃, CSCl—P₂O₅, CSCl—NH₄H₂PO₄, H₃BO₃—P₂O₅, H₃BO₃—NH₄H₂PO₄, B₂O₃—P₂O₅, B₂O₃—NH₄H₂PO₄, Cs₂O—PbO, Cs₂O—PbF₂, CsOH—PbO, CsOH—PbF₂, CsF—Bi₂O₃, CsF—MoO₃, CsBF₄—Bi₂O₃, CsBF₄—MoO₃, Cs₂CO₃—Li₄P₂O₇, CS₂CO₃—CSBO₂, Cs₂CO₃—NaF, Cs₂CO₃—NaCl, Cs₂CO₃—Li₄P₂O₇—NaF, Cs₂CO₃—Li₄P₂O₇—NaCl, Cs₂CO₃—Li₄P₂O₇—MoO₃, Cs₂CO₃—LiBO₂—MoO₃, Cs₂CO₃—H₃BO₃—P₂O₅, Cs₂CO₃—H₃BO₃—NH₄H₂PO₄, Cs₂CO₃—H₃BO₃—PbO, etc.

7. The method according to claim 6, wherein the composite fluxing agents, the molar ratio of KOH to B₂O₃ in the KOH—B₂O₃ system of the fluxing agent is 0.5-4:0.6-12; the molar ratio of KOH to P₂O₅ in the KOH—P₂O₅ system is 0.5-5:6-15; the molar ratio of KOH to NH₄H₂PO₄ in the KOH—NH₄H₂PO₄ system is 1-4:7-12; the molar ratio of K₂CO₃ to H₃BO₃ in the K₂CO₃—H₃BO₃ system is 0.5-3:0.8-16; the molar ratio of K₂CO₃ to B₂O₃ in the K₂CO₃—B₂O₃ system is 1-3:0.9-16; the molar ratio of K₂CO₃ to P₂O₅ in the K₂CO₃—P₂O₅ system is 0.5-2:6-12; the molar ratio of K₂CO₃ to NH₄H₂PO₄ in the K₂CO₃—NH₄H₂PO₄ system is 1-4:1.1-16; the molar ratio of KF to H₃BO₃ in the KF—H₃BO₃ system is 0.5-4:8-15; the molar ratio of KF to B₂O₃ in the KF—B₂O₃ system is 0.5-3:0.6-15; the molar ratio of KF to P₂O₅ in the KF—P₂O₅ system is 0.5-3:0.7-10; the molar ratio of KF to NH₄H₂PO₄ in the KF—NH₄H₂PO₄ system is 0.5-3:6-10; the molar ratio of KCl to H₃BO₃ in the KCl—H₃BO₃ system is 0.5-3.5:6-14; the molar ratio of KCl to B₂O₃ in the KCl—B₂O₃ system is 0.5-3.5:6-14; the molar ratio of KCl to P₂O₅ in the KCl—P₂O₅ system is 0.5-3.5:7-15; the molar ratio of KCl to NH₄H₂PO₄ in the KCl—NH₄H₂PO₄ system is 0.5-5:6-15; the molar ratio of K₂O to PbO in the K₂O—PbO system is 0.5-5: 6-16; the molar ratio of K₂O to PbF₂ in the K₂O—PbF₂ system is 0.5-5:6-16; the molar ratio of KOH to PbO in the KOH—PbO system is 0.5-5:6-16; the molar ratio of the KOH to PbF₂ in the KOH—PbF₂ system is 0.5-5:6-16; the molar ratio of the KF to Bi₂O₃ in the KF—Bi₂O₃ system is 0.5-5:6-16; the molar ratio of the KF to MoO₃ in the KF—MoO₃ system is 0.5-5:6-16; the molar ratio of the KBF₄ to Bi₂O₃ in the KBF₄—Bi₂O₃ system is 0.5-5:6-16; the molar ratio of the KBF₄ to MoO₃ in the KBF₄—MoO₃ system is 0.5-5:6-16; the molar ratio of K₂CO₃ to Li₄P₂O₇ in the K₂CO₃—Li₄P₂O₇ system is 0.5-3.5:7-15; the molar ratio of K₂CO₃ to KBO₂ in the K₂CO₃—KBO₂ system is 0.5-5:6-15; the molar ratio of K₂CO₃ to NaF in the K₂CO₃—NaF system is 0.5-3.5:7-15; the molar ratio of K₂CO₃ to NaCl in the K₂CO₃—NaCl system is 0.5-5:6-15; the molar ratio of K₂CO₃, Li₄P₂O₇ to NaF in the K₂CO₃—Li₄P₂O₇—NaF system is 0.5-5:6-16:0.6-16; the molar ratio of K₂CO₃, Li₄P₂O₇ to NaCl in the K₂CO₃—Li₄P₂O₇—NaCl system is 0.5-5:6-16:6-16; the molar ratio of K₂CO₃, Li₄P₂O₇ to MoO₃ in the K₂CO₃—Li₄P₂O₇— MoO₃ system is 0.5-5:6-16:6-16; the molar ratio of K₂CO₃, LiBO₂ to MoO₃ in the K₂CO₃— LiBO₂— MoO₃ system is 0.5-5:6-16:6-16; the molar ratio of K₂CO₃, H₃BO₃ to P₂O₅ in the K₂CO₃—H₃BO₃—P₂O₅ system is 0.5-5:6-16:6-16; the molar ratio of K₂CO₃, H₃BO₃ to NH₄H₂PO₄ in the K₂CO₃—H₃BO₃—NH₄H₂PO₄ system is 0.5-5:6-16:6-16; the molar ratio of K₂CO₃, H₃BO₃ to PbO in the K₂CO₃—H₃BO₃—PbO system is 0.5-5:6-16: 6-16; the molar ratio of RbOH to B₂O₃ in the RbOH—B₂O₃ system is 0.5-4:6-12; the molar ratio of RbOH to P₂O₅ in the RbOH—P₂O₅ system is 0.5-5:6-15; the molar ratio of RbOH to NH₄H₂PO₄ in the RbOH—NH₄H₂PO₄ system is 1-4:7-12; the molar ratio of Rb₂CO₃ to H₃BO₃ in the Rb₂CO₃—H₃BO₃ system is 0.5-3:0.8-16; the molar ratio of Rb₂CO₃ to B₂O₃ in the Rb₂CO₃—B₂O₃ system is 1-3:9-16; the molar ratio of Rb₂CO₃ to P₂O₅ in the Rb₂CO₃—P₂O₅ system is 0.5-2:0.6-12; the molar ratio of Rb₂CO₃ to NH₄H₂PO₄ in the Rb₂CO₃—NH₄H₂PO₄ system is 1-4:11-16; the molar ratio of RbF to H₃BO₃ in the RbF—H₃BO₃ system is 0.5-4:8-15; the molar ratio of RbF to B₂O₃ in the RbF—B₂O₃ system is 0.5-3:6-15; the molar ratio of RbF to P₂O₅ in the RbF—P₂O₅ system is 0.5-3:7-10; the molar ratio of RbF to NH₄H₂PO₄ in the RbF—NH₄H₂PO₄ system is 0.5-3:6-10; the molar ratio of RbCl to H₃BO₃ in the RbCl—H₃BO₃ system is 0.5-3.5:6-14; the molar ratio of RbCl to B₂O₃ in the RbCl—B₂O₃ system is 0.5-3.5:0.6-14; the molar ratio of RbCl to P₂O₅ in the RbCl—P₂O₅ system is 0.5-3.5:7-15; the molar ratio of RbCl to NH₄H₂PO₄ in the RbCl—NH₄H₂PO₄ system is 0.5-5:6-15; the molar ratio of Rb₂₀ to PbO in the Rb₂O—PbO system is 0.5-5: 6-16; the molar ratio of Rb₂₀ to PbF₂ in the Rb₂O—PbF₂ system is 0.5-5:6-16; the molar ratio of RbOH to PbO in the RbOH—PbO system is 0.5-5:6-16; the molar ratio of the RbOH to PbF₂ in the RbOH—PbF₂ system is 0.5-5:6-16; the molar ratio of the RbF to Bi₂O₃ in the RbF—Bi₂O₃ system is 0.5-5:6-16; the molar ratio of the RbF to MoO₃ in the RbF—MoO₃ system is 0.5-5:6-16; the molar ratio of the RbBF₄ to Bi₂O₃ in the RbBF₄—Bi₂O₃ system is 0.5-5:6-16; the molar ratio of the RbBF₄ to MoO₃ in the RbBF₄—MoO₃ system is 0.5-5:6-16; the molar ratio of Rb₂CO₃ to Li₄P₂O₇ in the Rb₂CO₃—Li₄P₂O₇ system is 0.5-3.5:7-15; the molar ratio of Rb₂CO₃ to RbBO₂ in the Rb₂CO₃—RbBO₂ system is 0.5-5:6-15; the molar ratio of Rb₂CO₃ to NaF in the Rb₂CO₃—NaF system is 0.5-3.5:0.7-15; the molar ratio of Rb₂CO₃ to NaCl in the Rb₂CO₃—NaCl system is 0.5-5:6-15; the molar ratio of Rb₂CO₃, Li₄P₂O₇ to NaF in the Rb₂CO₃—Li₄P₂O₇—NaF system is 0.5-5:6-16:6-16; the molar ratio of Rb₂CO₃, Li₄P₂O₇ to NaCl in the Rb₂CO₃—Li₄P₂O₇—NaCl system is 0.5-5:0.6-16:0.6-16; the molar ratio of Rb₂CO₃, Li₄P₂O₇ to MoO₃ in the Rb₂CO₃—Li₄P₂O₇— MoO₃ system is 0.5-5:6-16:6-16; the molar ratio of Rb₂CO₃, LiBO₂ to MoO₃ in the Rb₂CO₃— LiBO₂— MoO₃ system is 0.5-5:6-16:6-16; the molar ratio of Rb₂CO₃, H₃BO₃ to P₂O₅ in the Rb₂CO₃—H₃BO₃—P₂O₅ system is 0.5-5:6-16:6-16; the molar ratio of Rb₂CO₃, H₃BO₃ to NH₄H₂PO₄ in the Rb₂CO₃—H₃BO₃—NH₄H₂PO₄ system is 0.5-5:6-16:6-16; the molar ratio of Rb₂CO₃, H₃BO₃ to PbO in the Rb₂CO₃—H₃B₀₃—PbO system is 0.5-5:6-16: 6-16; the molar ratio of CsOH to B₂O₃ in the CsOH—B₂O₃ system is 0.5-4:6-12; the molar ratio of CsOH to P₂O₅ in the CsOH—P₂O₅ system is 0.5-5:6-15; the molar ratio of CsOH to NH₄H₂PO₄ in the CsOH—NH₄H₂PO₄ system is 1-4:7-12; the molar ratio of Cs₂CO₃ to H₃BO₃ in the Cs₂CO₃—H₃BO₃ system is 0.5-3:0.8-16; the molar ratio of Cs₂CO₃ to B₂O₃ in the Cs₂CO₃—B₂O₃ system is 1-3:9-16; the molar ratio of Cs₂CO₃ to P₂O₅ in the Cs₂CO₃—P₂O₅ system is 0.5-2:6-12; the molar ratio of Cs₂CO₃ to NH₄H₂PO₄ in the Cs₂CO₃—NH₄H₂PO₄ system is 1-4:1.1-16; the molar ratio of CsF to H₃BO₃ in the CsF—H₃BO₃ system is 0.5-4:8-15; the molar ratio of CsF to B₂O₃ in the CsF—B₂O₃ system is 0.5-3:6-15; the molar ratio of CsF to P₂O₅ in the CsF—P₂O₅ system is 0.5-3:7-10; the molar ratio of CsF to NH₄H₂PO₄ in the CsF—NH₄H₂PO₄ system is 0.5-3:6-10; the molar ratio of CsCl to H₃BO₃ in the CsCl—H₃BO₃ system is 0.5-3.5:0.6-14; the molar ratio of CsCl to B₂O₃ in the CsCl—B₂O₃ system is 0.5-3.5:6-14; the molar ratio of CsCl to P₂O₅ in the CsCl—P₂O₅ system is 0.5-3.5:7-15; the molar ratio of CsCl to NH₄H₂PO₄ in the CsCl—NH₄H₂PO₄ system is 0.5-5:6-15; the molar ratio of H₃BO₃ to P₂O₅ in the H₃BO₃—P₂O₅ system is 0.5-5:6-16; the molar ratio of H₃BO₃ to NH₄H₂PO₄ in the H₃BO₃—NH₄H₂PO₄ system is 0.5-5:6-16; the molar ratio of B₂O₃ to P₂O₅ in the B₂O₃—P₂O₅ system is 0.5-5:0.6-16; the molar ratio of B₂O₃ to NH₄H₂PO₄ in the B₂O₃—NH₄H₂PO₄ system is 0.5-5:6-16; the molar ratio of H₃B₀₃ to NH₄H₂PO₄ in the H₃BO₃—NH₄H₂PO₄ system is 0.5-5:6-16; the molar ratio of Cs₂O to PbO in the Cs₂O—PbO system is 0.5-5: 6-16; the molar ratio of Cs₂O to PbF₂ in the Cs₂O—PbF₂ system is 0.5-5:6-16; the molar ratio of CsOH to PbO in the CsOH—PbO system is 0.5-5:6-16; the molar ratio of the CsOH to PbF₂ in the CsOH—PbF₂ system is 0.5-5:6-16; the molar ratio of the CsF to Bi₂O₃ in the CsF—Bi₂O₃ system is 0.5-5:6-16; the molar ratio of the CsF to MoO₃ in the CsF—MoO₃ system is 0.5-5:6-16; the molar ratio of the CsBF₄ to Bi₂O₃ in the CsBF₄—Bi₂O₃ system is 0.5-5:6-16; the molar ratio of the CsBF₄ to MoO₃ in the CsBF₄—MoO₃ system is 0.5-5:0.6-16; the molar ratio of Cs₂CO₃ to Li₄P₂O₇ in the Cs₂CO₃—Li₄P₂O₇ system is 0.5-3.5:7-15; the molar ratio of Cs₂CO₃ to CsBO₂ in the Cs₂CO₃— CsBO₂ system is 0.5-5:6-15; the molar ratio of Cs₂CO₃ to NaF in the Cs₂CO₃—NaF system is 0.5-3.5:7-15; the molar ratio of Cs₂CO₃ to NaCl in the Cs₂CO₃—NaCl system is 0.5-5:6-15; the molar ratio of Cs₂CO₃, Li₄P₂O₇ to NaF in the Cs₂CO₃—Li₄P₂O₇—NaF system is 0.5-5:6-16:6-16; the molar ratio of Cs₂CO₃, Li₄P₂O₇ to NaCl in the Cs₂CO₃—Li₄P₂O₇—NaCl system is 0.5-5:0.6-16:0.6-16; the molar ratio of Cs₂CO₃, Li₄P₂O₇ to MoO₃ in the Cs₂CO₃—Li₄P₂O₇— MoO₃ system is 0.5-5:6-16:6-16; the molar ratio of Cs₂CO₃, LiBO₂ to MoO₃ in the Cs₂CO₃— LiBO₂— MoO₃ system is 0.5-5:0.6-16:6-16; the molar ratio of Cs₂CO₃, H₃BO₃ to P₂O₅ in the Cs₂CO₃—H₃BO₃—P₂O₅ system is 0.5-5:0.6-16:0.6-16; the molar ratio of Cs₂CO₃, H₃BO₃ to NH₄H₂PO₄ in the Cs₂CO₃—H₃BO₃—NH₄H₂PO₄ system is 0.5-5:6-16:6-16; the molar ratio of Cs₂CO₃, H₃BO₃ to PbO in the Cs₂CO₃—H₃BO₃—PbO system is 0.5-5:6-16: 6-16.

8. Use of the alkali metal borophosphates nonlinear optical crystals according to claim 4, characterized in that the alkali metal borophosphates nonlinear optical crystals are used for the second harmonic generator, the upper and lower frequency converters, the optical parametric oscillation, laser frequency converter, laser communication and other nonlinear optical devices.
